(19) United States
(12) Patent Application Publication
(10) Pub. No.: US 2012/0280273 A1
(43) Pub. Date: Nov. 8, 2012

(54) METHODS AND SUBSTRATES FOR LASER ANNEALING

(75) Inventors: Victor LENCHENKOV, Sunnyvale, CA (US); R. Daniel MCGRATH, Pittsford, NY (US)

(73) Assignee: APTINA IMAGING CORPORATION, George Town Grand Cayman (KY)

(21) Appl. No.: 13/177,022

(22) Filed: Jul. 6, 2011

Related U.S. Application Data
(60) Provisional application No. 61/481,396, filed on May 2, 2011.

(51) Int. Cl. H01L 29/12; H01L 21/268

(52) U.S. Cl. 257/183; 438/795; 257/E21.347; 257/E21.333; 257/E29.068

(57) ABSTRACT

Methods and substrates for laser annealing are disclosed. The substrate includes a target region to be annealed and a plurality of reflective interfaces. The reflective interfaces cause energy received by the substrate to resonate within the target region. The method includes emitting energy toward the substrate with a laser, receiving the energy with the substrate, and reflecting the received energy with a plurality of reflective interfaces embedded in the substrate to generate a resonance within the target region.

### CROSS REFERENCE TO RELATED APPLICATIONS

This application claims priority from U.S. Provisional Patent Application No. 61/481,396 filed May 2, 2011, the contents of which are incorporated herein by reference.

### FIELD OF THE INVENTION

The present invention relates generally to laser annealing, and more particularly, to methods and substrates that enable improvements in laser annealing.

### BACKGROUND OF THE INVENTION

In recent years, lasers have been widely used in a variety of applications including spectroscopy and materials processing. In materials processing applications, lasers are particularly useful for cutting, welding, or ablating certain materials due to their high energy output. One suitable use for this high energy is laser annealing.

Laser annealing involves using the energy emitted by a laser to heat part of a target substrate to a very high temperature (e.g., to the point of melting, evaporation and even ionization). The annealed substrate thereby becomes physically or chemically different from the original target substrate. The efficiency of a laser annealing process is governed at least in part by the degree to which the target substrate can be heated with very high spatial definition by the laser, and the percentage of energy from the laser that is absorbed by (and thus used to heat) the target substrate. There is an omnipresent desire for improving the efficiency of laser annealing processes.

### BRIEF DESCRIPTION OF THE DRAWINGS

The invention is best understood from the following detailed description when read in connection with the accompanying drawings, with like elements having the same reference numerals. When a plurality of similar elements are present, a single reference numeral may be assigned to the plurality of similar elements with a small letter designation referring to specific elements. When referring to the elements collectively or to a non-specific one or more of the elements, the small letter designation may be dropped. According to common practice, the various features of the drawings are not drawn to scale unless otherwise indicated. To the contrary, the dimensions of the various features may be expanded or reduced for clarity. Included in the drawings are the following figures:

FIG. 1 is a diagram illustrating an example substrate to be laser annealed in accordance with aspects of the present invention;

FIG. 2 is a diagram illustrating one example reflective interface of the substrate of FIG. 1;

FIG. 3 is a diagram illustrating another example reflective interface of the substrate of FIG. 1;

FIG. 4 is a diagram illustrating yet another example reflective interface of the substrate of FIG. 1;

FIG. 5 is a diagram illustrating still another example reflective interface of the substrate of FIG. 1;

FIG. 6 is a graph illustrating the absorption percentage of an example target region in accordance with aspects of the present invention; and

FIG. 7 is a flowchart illustrating an example method for laser annealing a substrate in accordance with aspects of the present invention.

### DETAILED DESCRIPTION OF THE INVENTION

The methods and substrates described herein are usable for creating a variety of components for electronic devices including, for example, films or coatings for use on image sensor pixels. The disclosed methods and substrates may enable more efficient and faster laser annealing than conventional annealing processes as well as complete substitution of high energy consuming conventional single crystal silicon wafer production which consist of very high temperatures ingots pulling technology followed by wafer slicing and grinding processes Additionally, the disclosed methods and substrates may be usable to create finished products that are beyond the capability of conventional annealing processes.

The example embodiments disclosed herein are particularly suitable for use in the laser annealing of semiconductor materials. Nonetheless, while the example embodiments of the present invention are described herein in the context of semiconductor materials, it will be understood by one of ordinary skill in the art that the invention is not so limited, and that the disclosed embodiments may be used in connection with other materials, such as conductors.

As used herein, the term “substrate” is intended to encompass any material on which it is desired to perform a laser annealing process. The use of the term “substrate” is not intended to limit the form or intended use of any of the disclosed embodiments. Additionally, as used herein, the term “energy” is intended to encompass all forms of electromagnetic radiation emitted by a laser. The use of the term “energy” is not intended to limit the disclosed embodiments to a particular wavelength or form of electromagnetic radiation.

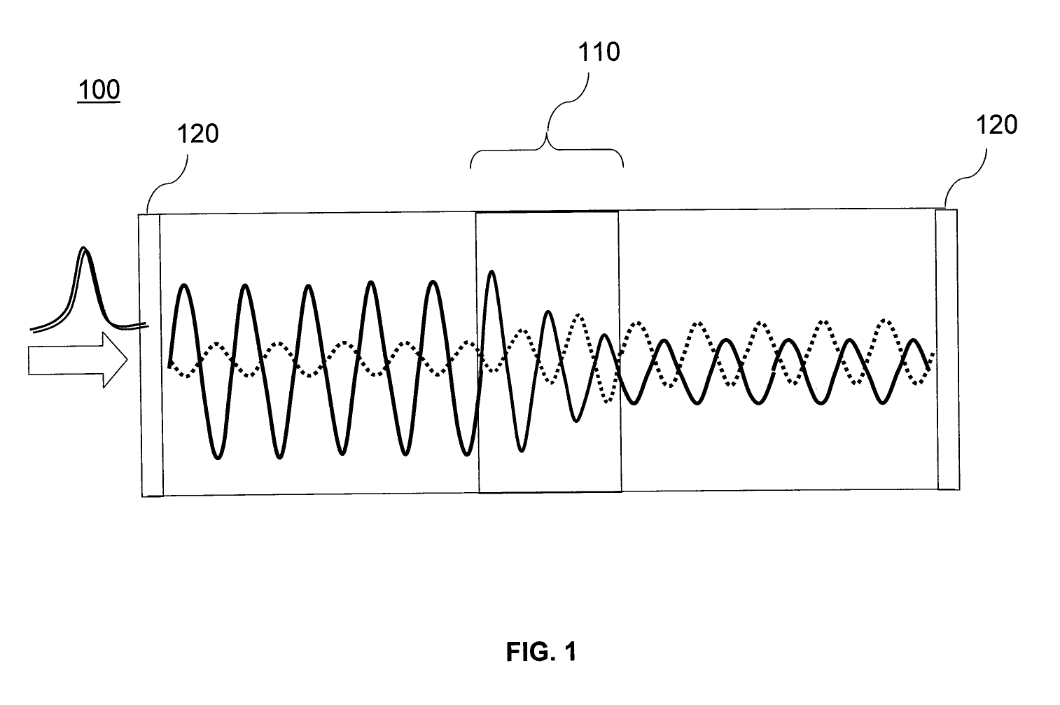

Referring now to the drawings, FIG. 1 illustrates an example substrate 100 to be laser annealed in accordance with aspects of the present invention. Substrate 100 may be, for example, an amorphous silicon (a-Si) semiconductor substrate. As a general overview, substrate 100 includes a target region 110 and a plurality of reflective interfaces 120. Additional details of substrate 100 are described below.

Target region 110 is the portion of substrate 100 that is desired to be annealed during the laser annealing process. Target region 110 may cover the entire portion of substrate 100, or alternatively, may be only a portion of substrate 100.

In an example embodiment, target region 110 forms only a portion of substrate 100, as shown in FIG. 1. Target region 110 may be positioned on an edge of substrate 100 or at a middle portion of substrate 100. Within substrate 100, target region 110 may comprise the same material as the surrounding material. Alternatively, target region 110 may comprise different material from the surrounding material. For example, the surrounding material may be selected to be substantially transparent to the energy emitted from the laser during the laser annealing process. For another example, the surrounding material may be selected based on its refractive index, in order to form the plurality of reflective interfaces, as will be discussed further herein. It may be desirable to provide additional material surrounding target region 110 in order to optimize the resonance of laser energy within target region 110. The additional material may then, if necessary, be removed following the laser annealing process through known processes (e.g., laser ablation, wet or dry etch).

Reflective interfaces 120 reflect the energy from the laser as it propagates within substrate 100. Reflective interfaces 120 are positioned so that they reflect the energy toward target region 110 (left to right for the solid line in FIG. 1, right to left for the dotted line in FIG. 1). Thereby, the plurality of reflective interfaces 120 cause the energy traversing substrate 100 to resonate within target region 110. As used herein, the terms “resonate” or “resonance” refer to standing wave resonance of the energy emitted from the laser within the target region 110 of substrate 100. The energy resonating within target region 110 may desirably improve the heating of the target region 110 of substrate 100. In particular, the resonance may increase the efficiency of the annealing process by enabling more absorption of the laser energy in the target region 110 and by heating the material to higher temperatures in the target region 110.

Reflective interfaces 120 may be positioned in front of and/or behind target region 110 (relative to the direction of the laser). Where reflective interfaces 120 are positioned in front of target region 110 relative to the direction of the energy emitted by the laser (i.e. the block arrow in FIG. 1), it is desirable that reflective interfaces 120 be at least partially transmissive. Accordingly, energy traversing substrate 100 may be allowed to enter target region 110 before it is reflected by reflective interfaces 120 (causing the above-described resonance). Partial reflectors and reflective interfaces forming the resonator may be made based on: 1) Fresnel index contrast reflections between different semiconductor materials; 2) Additional semiconductor material layer(s); 3) plasmon-based 3D structures; 4) photonic band gap filter structures; 5) geometrically set up resonators; or 6) a combination of any of 1-5 with absorption filters.

Examples of the reflective interfaces 120 of substrate 100 will now be described in accordance with aspects of the present invention. It will be understood that the example reflective interfaces 120 described herein are for the purposes of illustration, and are not intended to limit the structure of the reflective interfaces 120 of the present invention. It will be understood by one of ordinary skill in the art that the reflective interfaces 120 may be any suitable surface that reflects the energy (or a portion thereof) received by substrate 100 in order to cause resonance in target region 110. The orientation of reflective interfaces 120 in the example embodiments set forth below approximate the resonance effect of a Fabry-Perot interferometer within the target region 110 of substrate 100, as would be understood by one of ordinary skill in the art from the description herein.

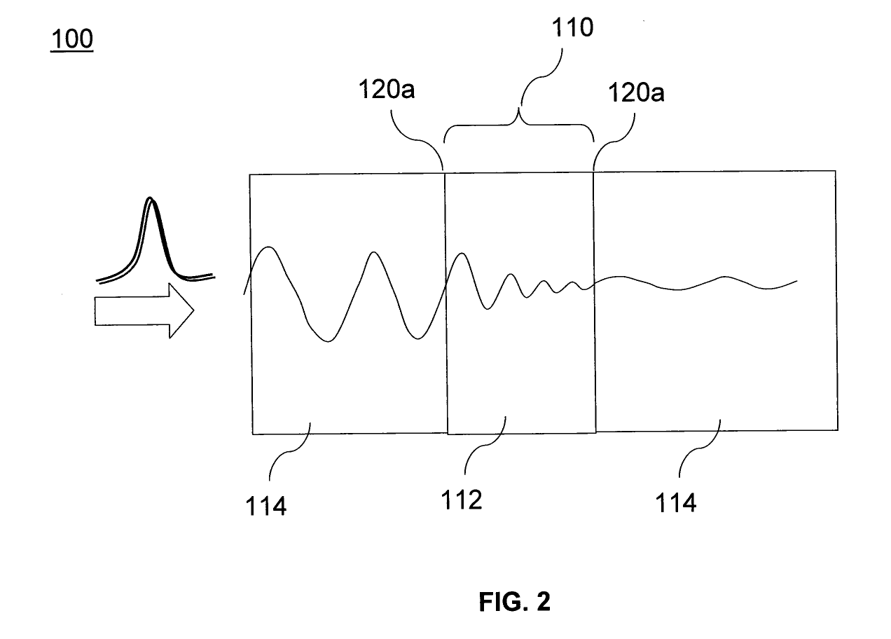

In one example embodiment, the plurality of reflective interfaces 120 comprises boundaries between two materials having different complex refractive indexes (complex refractive index consist of real part responsible for light refraction and an imaginary part responsible for light absorption), as shown in FIG. 2. For example, target region 110 may include a first semiconductor material 112 having a first refractive index. First material 112 may be, for example, amorphous silicon (a-Si). Substrate 100 may include a second semiconductor material 114 disposed on either side of target region 110 that has a different refractive index than the material of target region 110. Second material 114 may be, for example, SiO₂, SiN, SiC, and/or HfO₂. As set forth above, it may be desirable that second material 114 be substantially transparent to the energy emitted from the laser during the laser annealing process. In this embodiment, boundaries 120a between the different materials reflect the energy back and forth within target region 110, thereby causing resonance of the received energy.

In another example embodiment, the plurality of reflective interfaces 120 comprise layers of reflective material positioned on opposite sides of target region 110. The shape, size, and composition of the reflective material layers may be chosen based on a number of characteristics, as shown below.

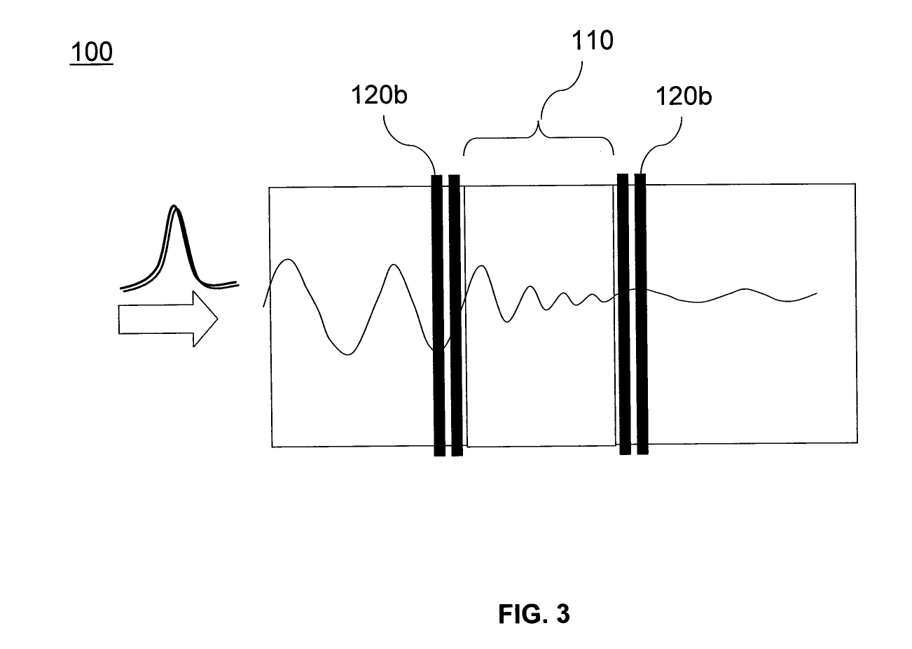

For example, substrate 100 may include reflective material layers formed as interference filters 120b on either side of target region 110, as shown in FIG. 3. Interference filters 120b may be formed, for example, using conventional vapor deposition techniques. Multiple layers of material having different refractive and absorption properties (real and imaginary parts of the complex refractive index, respectively) may be deposited to form diffraction gratings that are tuned to concentrate/deposit laser energy in a particular wavelength band. Interference filters 120b may be designed to transmit portions of the energy that are not of interest, while reflecting (and confining) certain wavelength ranges that are desired to be absorbed within target region 110. In this way, interference filters 120b may be used to generate target regions 110 that are only sensitive to predetermined wavelength ranges of energy.

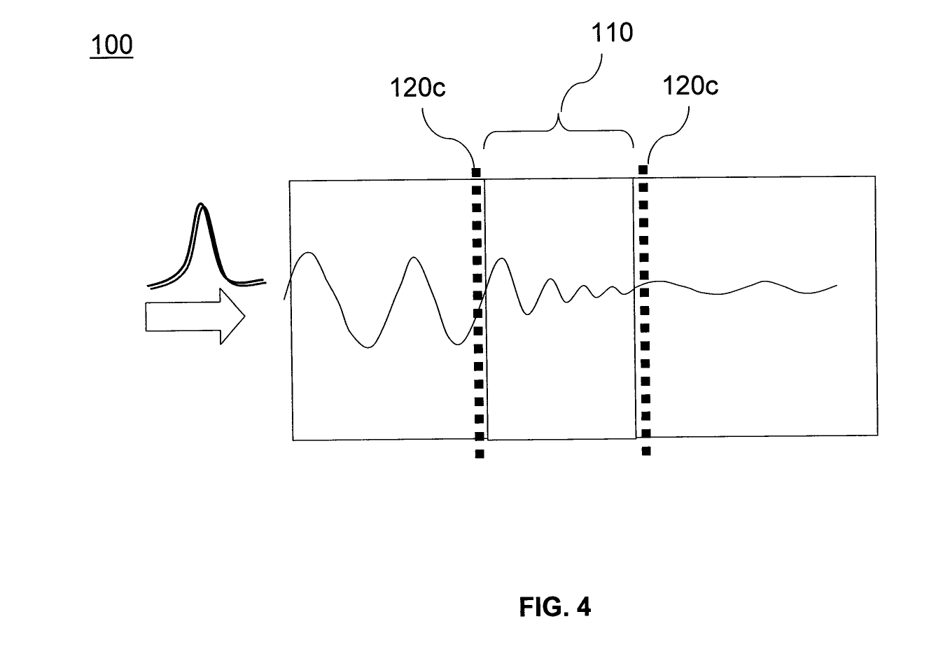

For another example, the layers of reflective material may be formed as three-dimensional (3D) structures 120c embedded in substrate 100, as shown in FIG. 4. The 3D structures 120c may be shaped as dots, lines, or other suitable shapes. 3D structures 120c may be formed, for example, using techniques similar to those used to form shallow trench isolation structures. One suitable shallow trench isolation process for forming 3D structures 120c is set forth in U.S. Pat. No. 6,897,120 to Trapp, the contents of which are incorporated herein by reference. One suitable material for 3D structures 120c includes plasmon-based conductive material, such as W, Al, Cu, Au, Ag, and/or TiN. Another suitable material for 3D structures 120c includes a dielectric material such as, for example, SiN, SiC, SiO₂, and/or HfO₂.

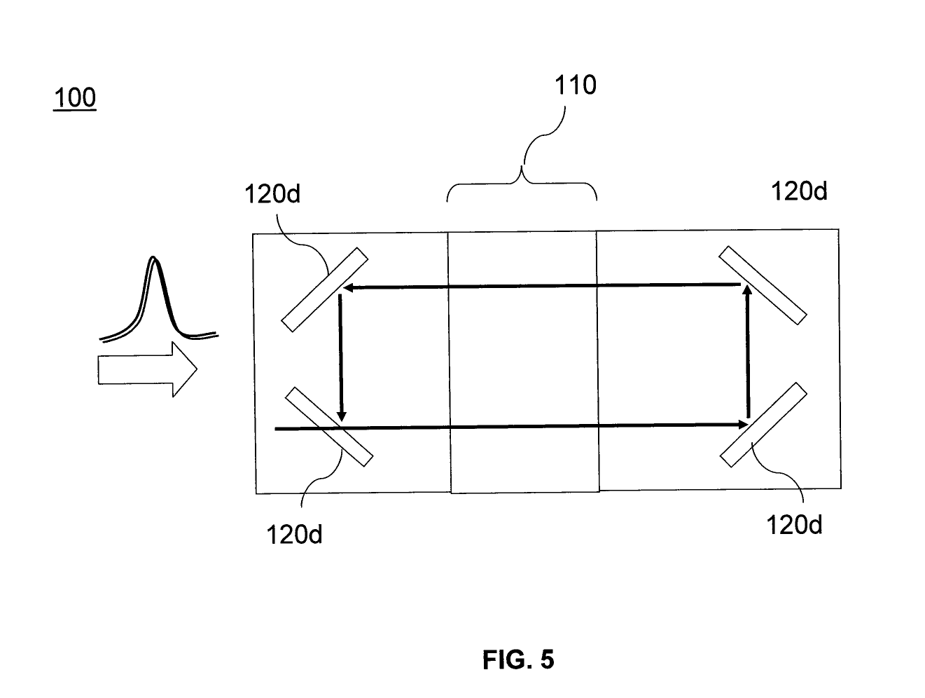

In yet another example embodiment, the plurality of reflective interfaces 120 comprise surfaces oriented to reflect the energy received by substrate 100 in different directions, as shown in FIG. 5. For example, energy received by substrate 100 may propagate in a first direction through substrate 100. Substrate 100 may include a reflective surface 120d oriented to reflect the energy in a second direction not parallel to the first direction (e.g., orthogonally in FIG. 5). This may desirably allow the energy received by substrate 100 to resonate over a larger portion of the target region 110, and further improve the absorption by and heating of target region 110. Reflective surface 120d may be formed, for example, using any of the processes described above with respect to the other embodiments of substrate 100. Suitable materials for use in forming reflective surface 120d include, for example, Si/SiO₂, Si/Air interfaces, Al, Au, Ag, W, polycrystalline Si, and/or amorphous Si.

It will be understood by one of ordinary skill in the art that the reflective interfaces 120 described above are not limited to reflecting all of the energy received by substrate 100. As described with respect to interference filters 120b, one or all of the reflective interfaces may be designed to reflect only a predetermined wavelength range of the energy received by the substrate 100. Accordingly, substrate 100 may be configured to resonate in predetermined wavelength ranges of energy using reflective interfaces 120, depending on the emission spectrum of the laser used for the annealing process, the laser pulse bandwidth, and/or its shape, laser energy per pulse, and laser pulse duration.

Additionally, the wavelength range for a respective substrate 100 may be predetermined based on the shapes, sizes, and materials of target region 110 and reflective interfaces 120. For example, the depth of target region 110 (in the direction of propagation of the emitted energy) may be lengthened or shortened based on the wavelength of the energy emitted by the laser. Further, the positioning and distance between reflective interfaces 120 may be altered based on the wavelength of the energy emitted by the laser. Where the reflective interfaces comprise boundaries between different materials, the indexes of refraction of those materials may be chosen based on the wavelength of the energy emitted by the laser. Finally, where reflective interfaces 120 comprise layers of reflective material, the reflective material may be chosen based on the wavelength of the energy emitted by the laser. The selection of shapes, sizes, and materials for target region 110 and reflective interfaces 120 to optimize the resonance of a predetermined wavelength range of energy will be understood by one of ordinary skill in the art from the description herein.

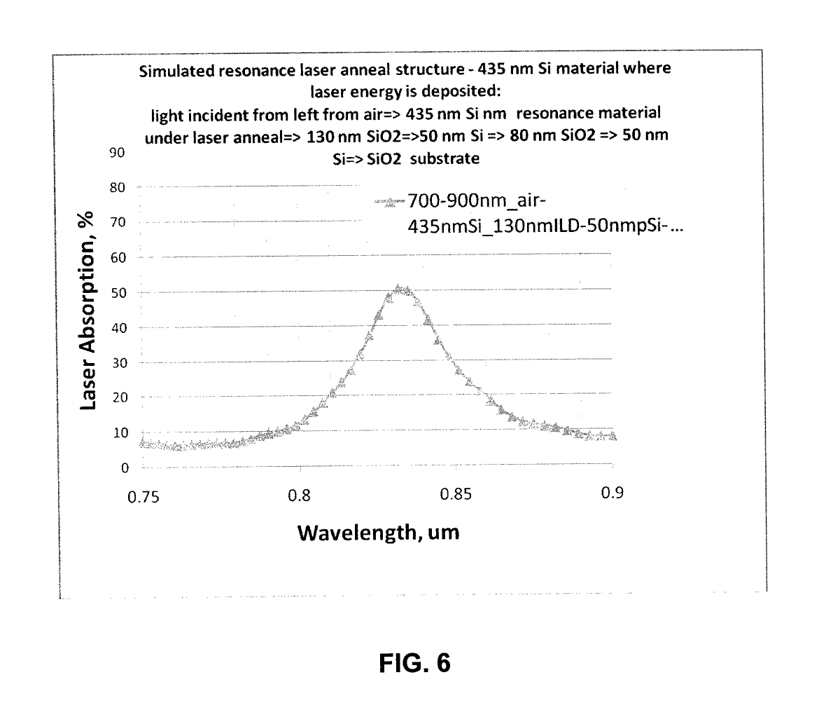

The tuning of the wavelength range of substrate 100 is now described with reference to FIG. 6. The laser annealing process may, for example, be performed with a laser emitting energy in a wavelength band of 800-850 nm. As such, it will be desired that the target region of a substrate absorb energy having wavelengths in that range. This substrate may be designed to have a target region with a depth of approximately 435 nm of silicon. Reflective interfaces such as interference filters may be positioned on either side of the target region at a distance of approximately 130 nm from the edge of the target region. The target region may be surrounded on either side by a material that is substantially optically transparent in the predetermined wavelength range. Similarly, the interference filters may be transmissive for wavelengths outside of the predetermined wavelength range. With the above structure, when energy emitted by the laser is received by the substrate, the wavelengths falling within the predetermined wavelength band will resonate within the target region. This greatly increases the absorption of the energy emitted by the laser, as shown in FIG. 6.

While different embodiments of reflective interfaces 120 are illustrated separately in FIGS. 2-5, it will be understood that substrate 100 may incorporate any combination of the above interfaces, or two or more different types of reflective interfaces 120, in order to maximize resonance of the received energy within target region 110. Different types of reflective interfaces 120 may be positioned differently within substrate 100 based on the wavelength of energy desired to be absorbed within target region 110, as set forth above.

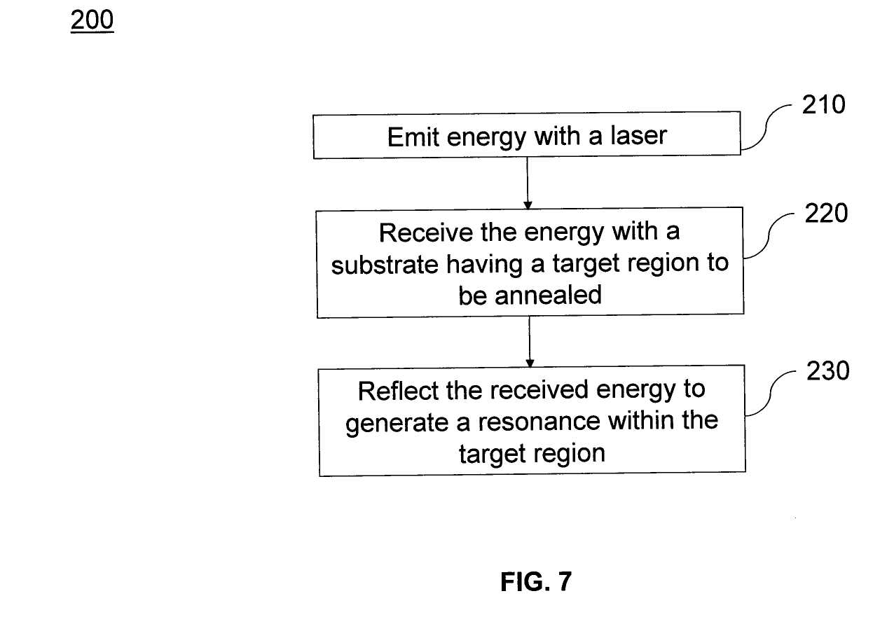

FIG. 7 is a flowchart illustrating an example method 200 for laser annealing a substrate in accordance with aspects of the present invention. Method 200 may desirably be implemented, for example, an amorphous silicon (a-Si) semiconductor substrate. As a general overview, method 200 includes emitting energy with a laser, receiving the energy with the substrate, and reflecting the received energy to generate a resonance. Additional details of method 200 are described herein with respect to substrate 100.

In step 210, energy is emitted with a laser. In an example embodiment, a laser emits energy toward substrate 100. The type and manner of emitting this energy will be described herein.

In an example embodiment, the laser used for method 200 is an ultra-fast pulsed laser. The laser is configured to emit ultra-fast laser pulses having a duration of, for example, from 10 fs to 1 ns. The laser may have a gap of, for example, 100 fs between each laser pulse. The parameters of the pulse such as duration and wavelength may be chosen based on the absorption properties of the target region, as would be understood to one of ordinary skill in the art from the description herein.

It may be particularly desirable to vary the wavelength or duration of the laser pulses during step 210. Varying the wavelength or duration of laser pulses may be useful to account for changes in the absorption of energy by target region 110 during the annealing process. For example, it may be desirable to emit shorter pulses more rapidly as the material in target region 110 rises in temperature during the annealing process. For another example, it may be desirable to emit pulses having different wavelengths to improve absorption by any materials that are created (for example, transient materials) during the annealing process. Suitable lasers for performing step 210 include, for example, Nd:YAG with a wavelength of 1064 nm and harmonics of 532, 266, etc.; or Ti—Al₂O₃ with a wavelength range 650-1100 nm and its harmonics.

While step 210 describes emitting energy with a single laser, it will be understood that the invention is not so limited. Step 210 may involve emitting pulses from two or more lasers toward substrate 100. Further, each of the lasers utilized in step 210 may emit pulses having different durations, wavelengths, and/or associated energies. It may be desirable to utilize two or more lasers in order to more precisely control the heating of target region 110 in substrate 100.

In step 220, the energy is received by the substrate. In an example embodiment, substrate 100 receives the energy from the laser. Substrate 100 has a target region 110 to be annealed by the laser energy.

In step 230, the received energy is reflected within the substrate. In an example embodiment, substrate 100 includes a plurality of reflective interfaces 120 embedded within substrate 100. The reflective interfaces 120 reflect the received energy in such a way as to generate a resonance within the target region 110 of substrate 100.

As set forth above with respect to FIG. 2, the received energy may be reflected at a boundary between two different types of material. Alternatively, as described above with respect to FIGS. 3 and 4, the received energy may be reflected using layers of reflective material positioned on opposite sides of the target region 110. In addition, as set forth above with respect to FIG. 5, the received energy may be reflected in a direction not parallel to the direction of propagation of the energy emitted by the laser.

It will be understood that method 200 is not limited to the above steps, but may include alternative steps and additional steps, as would be understood by one of ordinary skill in the art from the description herein.

For one example, it may be desirable to reflect only a predetermined wavelength range of the energy received by substrate 100, as set forth above. Accordingly, step 230 may include reflecting a predetermined wavelength range of the received energy to generate a resonance of only the predetermined wavelength range within target region 110.

For another example, it may be desirable to remove excess or unnecessary material following the laser annealing process. As set forth above, substrate 100 may include additional material or layers surrounding target region 110 in order to promote resonance of the energy emitted by the laser. It may be desirable that the final annealed substrate not include this additional material. Accordingly, method 200 may include the step of processing the substrate after step 230. This processing step may include removing excess material and/or removing the reflective interfaces 120 surrounding target region 110. This removal may be performed by, for example, laser ablation.

Aspects of the present invention relate to methods and substrates for laser annealing.

In accordance with one aspect of the present invention, an example method for laser annealing a substrate is disclosed. The method comprises the steps of emitting energy toward the substrate with a laser, receiving the energy with the substrate, the substrate having a target region to be annealed, and reflecting the received energy with a plurality of reflective interfaces embedded in the substrate to generate a resonance within the target region.

In accordance with another aspect of the present invention, an example substrate for laser annealing is disclosed. The substrate comprises a target region to be annealed and a plurality of reflective interfaces. The reflective interfaces cause energy received by the substrate to resonate within the target region.

The above aspects of the present invention may achieve advantages not present in prior art annealing processes, as set forth below. The disclosed annealing methods may be effective to confine substantially all energy emitted by the laser to a specific target region of the substrate. This can spatially and temporally localize the heating of the substrate, and thereby enable more efficient and faster laser annealing than conventional annealing processes, along with higher annealing temperatures (e.g., complete substitution of high energy consuming conventional single crystal silicon wafer production which consist of ingots pulling technology followed by wafer slicing and grinding processes). Additionally, the disclosed methods and substrates may be usable to create finished products that are beyond the capability of conventional annealing processes. For example, the disclosed annealing methods may heat amorphous silicon (a-Si) to sufficiently high temperatures to cause re-crystallization of the material. This may lead to the formation of new structures such as crystalline silicon (c-Si).

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A method for laser annealing a substrate comprising the steps of:
emitting energy toward the substrate with a laser;
receiving the energy with the substrate, the substrate having a target region to be annealed; and
reflecting the received energy with a plurality of reflective interfaces embedded in the substrate to generate a resonance within the target region.

2. The method of claim 1, wherein the emitting step comprises:
emitting ultra-fast laser pulses toward the substrate.

3. The method of claim 2, wherein the ultra-fast laser pulses have a duration of from 10 fs to 1 ns.

4. The method of claim 2, further comprising the step of:
varying the wavelength of the laser pulses during the emitting step.

5. The method of claim 2, further comprising the step of:
varying the duration of the laser pulses during the emitting step.

6. The method of claim 1, wherein
the substrate comprises a first semiconductor material and a second semiconductor material, and
the reflecting step comprises reflecting the received energy at a boundary between the first semiconductor material and the second semiconductor material.

7. The method of claim 1, wherein the reflecting step comprises:
reflecting the received energy with a layer of reflective material positioned on opposite sides of the target region.

8. The method of claim 1, wherein
the receiving step comprises receiving energy propagating in a first direction with the substrate, and
the reflecting step comprises reflecting the received energy in a second direction not parallel to the first direction.

9. The method of claim 1, wherein the reflecting step comprises:
reflecting a predetermined wavelength range of the received energy to generate a resonance of the predetermined wavelength range within the target region.

10. The method of claim 1, further comprising the step of:
processing the substrate after the reflecting step.

11. A substrate for laser annealing comprising:
a target region to be annealed; and
a plurality of reflective interfaces, the reflective interfaces causing energy received by the substrate to resonate within the target region.

12. The substrate of claim 11, wherein
the target region comprises a first semiconductor material,
the substrate further comprises a second semiconductor material different from the first semiconductor material positioned on opposite sides of the target region, and
the plurality of reflective interfaces comprises the boundaries between the first semiconductor material and the second semiconductor material.

13. The substrate of claim 11, wherein the plurality of reflective interfaces comprises layers of reflective material positioned on opposite sides of the target region.

14. The substrate of claim 13, wherein the layers of reflective material comprise interference filters.

15. The substrate of claim 13, wherein the layers of reflective material comprise three-dimensional structures embedded in the substrate.

16. The substrate of claim 15, wherein the three-dimensional structures comprise plasmon-based conductive material.

17. The substrate of claim 15, wherein the three-dimensional structures comprise dielectric material.

18. The substrate of claim 11, wherein
the energy received by the substrate propagates in a first direction, and
the plurality of reflective interfaces comprise at least one reflective interface configured to reflect the energy in a second direction not parallel to the first direction.

19. The substrate of claim 11, wherein the plurality of reflective interfaces are configured to cause a predetermined wavelength range of the energy received by the substrate to resonate within the target region.
